(19) United States
(12) Patent Application Publication
(10) Pub. No.: US 2005/0001661 A1
(43) Pub. Date: Jan. 6, 2005

(54) Digital phase locked loop

(76) Inventor: Zvi Regev, West Hills, CA (US)

Correspondence Address: ZVI REGEV, 24217 HIGHLANDER RD., WEST HILLS, CA, 91307, US

(21) Appl. No.: 10/696,602

(22) Filed: Oct. 28, 2003

Related U.S. Application Data
(60) Provisional application No. 60/421,857, filed on Oct. 29, 2002.

(51) Int. Cl. H03L 7/06

(52) U.S. Cl. 327/156

(57) ABSTRACT

The present invention describes an all digital phase locked loop utilizing a numerically controlled oscillator instead of a voltage controlled oscillator, and in a certain embodiment employs a phase digitizer as part of the phase detector.

### AREA OF THE INVENTION

This invention deals with digital synthesis of waveforms, and in particular with the generation of such signal in phase and frequency synchronization with a reference signal, utilizing phase locked loops.

### BACKGROUND OF THE INVENTION

The phase locked loop (PLL) is a closed loop electronic servo whose output lock onto and tracks an input reference signal. Phase lock is obtained the phase of the output signal with that of a reference, and any phase difference is converted into an error correcting voltage. This error voltage changes the output signal phase to make it track the input.

The servo system is comprised of three basic partitions; a phase detector, a loop filter, and a voltage (or current) controlled oscillator (VCO), as shown in FIG. 2.

When the phase difference between the VCO output and the reference is constant, the loop is locked. If either the reference input or the VCO output changes phase, the phase detector and the loop filter produce a DC error voltage, proportional in magnitude and polarity to the signal phase change. This error voltage changes the phase of the VCO by altering its frequency, until it lock on the reference input.

To understand the operation of a closed loop servo system refer to FIG. 1. The following relationships characterize the closed servo loop:

$${θ}_{e} ( s ) = \frac{1}{1 + G ( s ) H ( s )} + {θ}_{r} ( s ) and {θ}_{o} ( s ) = \frac{G ( s )}{1 + G ( s ) H ( s )} + {θ}_{r} ( s ) ,$$

wherein θᵣ(s) is the input phase, θₒ(s) is the output phase, θₑ(s) is the phase error, G(s) is the feedforward transfer function, and H(s) is the feedback transfer function.

There are various types and orders for PLLs. The order of a PLL refers to the degree of the polynomial expression 1+G(s)H(s)=0, which is termed the characteristic equation of the loop. The roots of the characteristic equation become the poles of the closed loop overall transfer function. The type of the PLL refers to the number of poles in the loop transfer function, which are located at the origin of the S-plane. Type 1 PLLs typically utilize a flip-flop, or a sample and hold device to detect the phase error between the reference and the output, while type 2 PLLs typically use a phase/frequency detector to generate the phase error voltage.

Type 2 PLL has two pure integrators (1/S²). This approach is utilized when a coherency to a received signal is required, as this type of loop maintains a steady state zero phase error for all operating conditions.

The basic type 2 PLL take the form shown in FIG. 4. The phase detector is designed to detect phase errors of either polarity relative to the reference signal and produce the properly polarized commands necessary to correct the VCO. The lowpass filter must include an integrator for storing the proper VCO control voltage during phase lock. The basic transfer characteristics for each individual function in the loop are:
Kₚ the phase detector gain constant in volts per radian;
K_{f} the filter transfer function

$${K}_{f} = \frac{1 + {R}_{2} CS}{{R}_{1} CS} = \frac{1 + {T}_{1} S}{{T}_{2} S}$$
Kₒ the VCO sensitivity in radians/sec/volts.

The output to input ratio for this loop is

$$\frac{{θ}_{o} ( s )}{{θ}_{1} ( s )} = \frac{{K}_{p} {K}_{f} {K}_{o}}{S + {K}_{p} {K}_{f} {K}_{o}} = \frac{1 + {T}_{1} S}{\frac{{S}^{2} {T}_{2}}{{K}_{p} {K}_{o}} + 1 + {T}_{1} S}$$

The loop bandwidth, or natural frequency is

$${ω}_{n} = \sqrt{\frac{{K}_{p} {K}_{o}}{{T}_{2}}}$$

And the damping factor is

$$ζ = \sqrt{\frac{{K}_{p} {K}_{o}}{{T}_{2}}} ( \frac{{T}_{1}}{2} )$$

Since Kₚ, and Kₒ are typically fixed, the parameters T₁, and T₂ are the variables used to control the loop characteristics. These parameters are derived as:

$${T}_{2} = \frac{{K}_{p} {K}_{o}}{{ω}_{n}^{2}} {T}_{1} = \frac{2 ζ}{{ω}_{n}}$$

And the components of the filter are:

$${R}_{1} = \frac{{K}_{p} {K}_{o}}{{ω}_{n}^{2} C} {R}_{2} = \frac{2}{{ω}_{n} C}$$

This invention describes a phase locked loop wherein a numerically controlled oscillator is used instead of a VCO, counters and digital integrators replace the loop filter and its components, and in a specific case a direct phase digitizer and a subtractor replace the traditional phase detector.

An embodiment of a digital phase locked loop is shown in FIG. 7. This PLL comprises a modified phase detector, a digital loop filter and a numerically controlled oscillator.

A numerically controlled oscillator (NCO) is a circuit wherein the output signal phase and frequency are directly controlled by digital numerical data inputs. The basic NCO shown in FIG. 5, is comprised of an adder, a register, a sine lookup (cosine) table, and a digital to analog converter. The numerical input is the desired phase difference ΔΘ over a period of one clock cycle T_{c}. On every clock cycle, the adder adds ΔΘ+Θ(k), wherein Θ(k) is the accumulated phase on clock cycle k. The number of bits in the adder and the register is n. Whenever the accumulated phase Θ(k) reaches 2ⁿ the accumulation rolls over and starts accumulating from zero. As the process of accumulation continues, the rollover is repeated, wherein the rate of repetition is defined by the numerical input. The larger the number at the input, the more frequently will the accumulator rollover. As the output of the accumulator is the accumulated phase Θ(k), each rollover indicates the end one cycle, and the beginning of a new cycle of the output signal.

Typically it is desirable for the oscillator to have an analog sinusoidal output. A sine lookup table, followed by a digital to analog converter is typically used to convert the accumulated phase Θ(k) into an analog (voltage or current) output.

The coefficient for the NCO can be determined as follows: The numerical input to the NCO is m, and the clock frequency of the NCO is F_{c}, and the actual angular output frequency is

$${ω}_{o} = 2 \prod {F}_{c} \frac{m}{{2}^{M}}$$

wherein M is the number of bits in the NCO's adder. Therefore,

$${K}_{o} = 2 \prod \frac{{F}_{c}}{{2}^{M}} .$$

The phase detector is a device that detects the phase difference (error) between the reference signal and the output signal, and generates an output signal of a magnitude proportional to the size of the error, and in a polarity, which will cause the VCO to correct for the error.

In the digital realm the desired presentation of the error is a numerical quantity. An embodiment of a phase detector capable of generating a numerical output as a measure of the error is shown in FIG. 6. This is a modified version of the standard phase detector wherein an EXOR gate and a counter are added to provide the numerical output. The output of the EXOR (4) controls the counter such that when the line is “high” the counter counts up, and when the line is “low”, the counter resets to zero. If the time (phase error) between the reference and the output is δt, and the frequency of the clock to the counter is F_{c}, then the output of the counter is N=δt×F_{c}. The coefficient Kₚ of the detector can be calculated by determining the phase difference

$$θ = 2 \prod \frac{δ t}{{T}_{0}}$$

Wherein T₀ is the period of the reference input signal. The value N is therefore

$$N = \frac{θ {T}_{0}}{2 Π} {F}_{c} And {K}_{p} = \frac{{T}_{0} {F}_{c}}{2 Π} .$$

The properties of the components of the loop filter can be determined from the desired dynamic properties of the loop, ωₙ, and ζ. As

$${T}_{2} = \frac{{K}_{p} {K}_{o}}{{ω}_{n}^{2}} , and {T}_{1} = \frac{2 ζ}{{ω}_{n}} .$$

Viewing the loop filter as an active filter with an amplifier as shown in FIG. 4, its response is given by

$${V}_{a} = {V}_{p} \frac{{R}_{2}}{R 1} + {V}_{p} \frac{t}{{R}_{1} C} + {V}_{c} ( 0 )$$

for 0<t<T₀, wherein Vₚ is the voltage output of the phase detector from t=0 to t=T₀ (the input signal period), and V_{c}(0) is the voltage on the capacitor at time 0. For

$${R}_{1} = \frac{{K}_{p} {K}_{o}}{{ω}_{n}^{2} C} and {R}_{2} = \frac{2}{{ω}_{n} C} then \frac{{R}_{2}}{{R}_{1}} = \frac{2 {ω}_{n}}{{K}_{p} {K}_{o}} = α$$

Since the loop is digital, the amplifier response can be viewed as an accumulator (20) followed by an adder (23)as shown in FIG. 8. The accumulator (20) replaces the integrator t/R₁C, and the adder (23) adds a constant of R₂/R₁ to the output of the accumulator. In this implementation the accumulator accumulates the value of N on each accumulator clock (24), which is at a rate of T₀/T₂. The clock to the accumulator (20) is derived from the clock period T_{c}. If T_{c}=βT₀, wherein T₀ is the period of the input reference, then for the accumulator the clock (24) period is Tₐ=T_{c}/βT₂. For simplicity, T₂ may be selected such that βT₂ is a power of 2, to enable easy scaling of the accumulator clock period.

The adder that follows the accumulator adds a constant αN. For simplicity ωₙ can be selected such that α is a power of 2, and thus the scaling of N is obtained by shifting the bits.

Another embodiment for a digital phase lock loop is shown in FIG. 9. The PLL in this embodiment is comprised of a digital phase sampler, a subtractor, a digital filter, and a numerically controlled oscillator.

The digital phase digitizer (40) samples the input signal (49) on every clock transition, and reports the instantaneous phase of the input signal at the time of the clock transition. The NCO (43) used in this embodiment is modified to output phase information instead of the typical analog voltage amplitude, as shown in FIG. 10. A subtractor subtracts the instantaneous phase generated by the phase digitizer (44), from the instantaneous phase of the NCO (45). The output (46) of the subtractor (41), is the phase error, in terms of phase, and the coefficient of this kind of phase discrimination is therefore Kₚ=1. The loop filter is similar to the one discussed earlier, and is used to control the dynamic properties of the loop.

Other embodiments of the digital phase locked loop are shown in FIGS. 11, and 12.. These embodiments describe type 1 phase locked loops, and utilize a digital UP/DOWN counter as the loop integrator.

### DESCRIPTION OF THE DRAWINGS

FIG. 1, shows a basic servo loop diagram.

FIG. 2, shows a basic phase locked loop.

FIG. 3, shows a type 1 PLL.

FIG. 4, shows a type 2 PLL.

FIG. 5, shows an embodiment of a numerically controlled oscillator (NCO).

FIG. 6, shows an embodiment of a modified phase detector.

FIG. 7, shows a block diagram of a digital phase locked loop (PLL).

FIG. 8, shows a block diagram of a digital filter for a digital PLL.

FIG. 9, shows a block diagram of a different embodiment of a digital PLL.

FIG. 10, shows an embodiment of a modified NCO.

FIG. 11, shows a block diagram of a type 1 digital PLL.

FIG. 12, shows a block diagram of an alternative type 1 digital PLL.

FIG. 13, shows an embodiment of a digital loop filter for a digital PLL.

FIG. 14, shows an embodiment of a phase digitizer.

FIG. 15, shows an embodiment of the phase quantizer section of the phase digitizer.

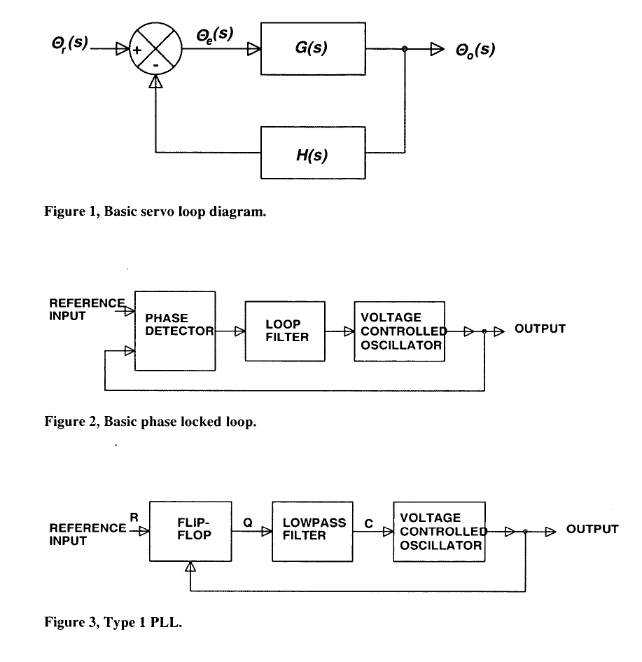

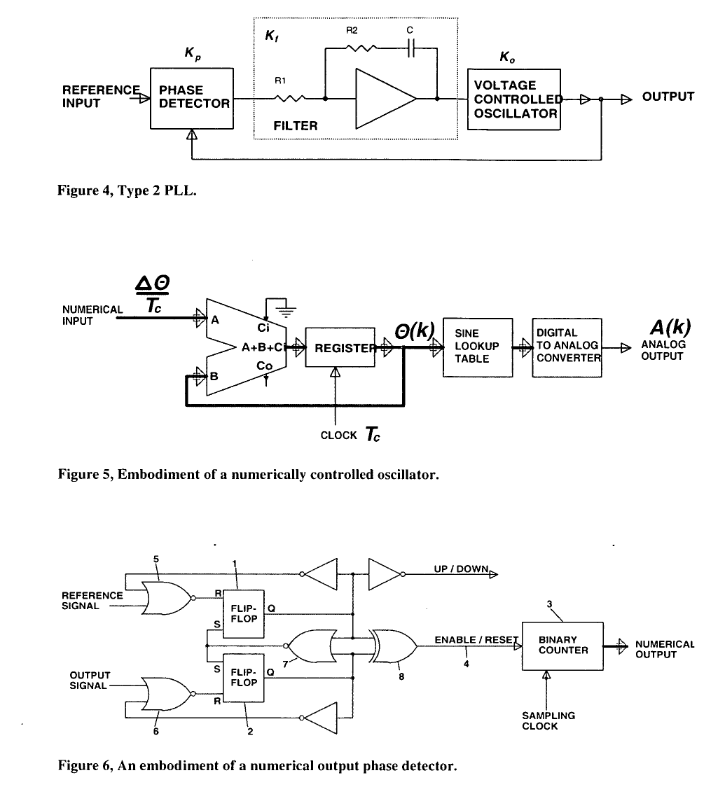

### DESCRIPTION OF THE INVENTION

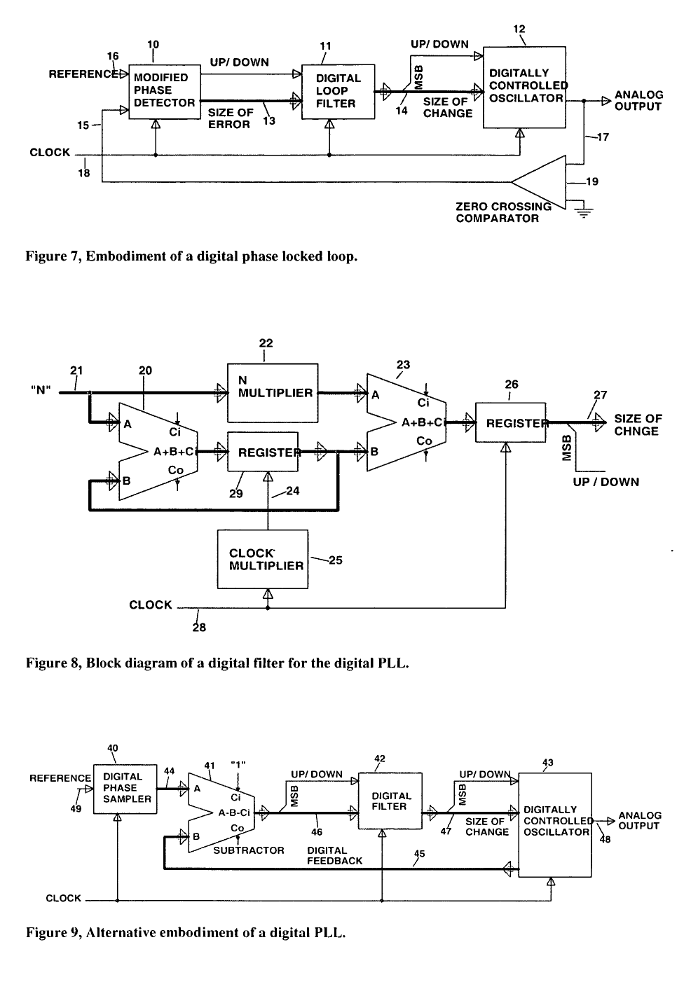

To describe the invention, one embodiment is best understood referring to FIGS. 6, 7, 10, and 13. FIG. 7, shows an embodiment of a digital phase locked loop, comprised of a modified phase detector, a digital loop filter, and a modified numerically controlled oscillator.

An embodiment of the modified phase detector is shown in FIG. 6. In steady state conditions, both flip-flops (1, and 2) are set (Q outputs are “1”), and the output (4) of the EXOR gate (8) is low. Under these conditions the gate (5, and 6) are enabled and the counter (3) is reset to “0”. On a transition from “1” to “0” on either of the inputs, a flip-flop associated with that input is reset, causing the output (4) of the EXOR gate (8) to change to “1”, enabling the counter (3) to count UP, at the rate of its clock. Upon the transition from “1” to “0” on the other input to the detector, the other flip-flop is reset. This causes the output (4) of the EXOR gate (8) to change to “0”, resetting the counter (3), and output of the NOR gate (7) changes to “1”, setting both flip-flops to their steady state condition. Once the flip-flops are set, the output of the NOR gate (7) changes back to “0”, and the detector is ready for the next input transitions. The numerical output of the counter is indicative of the phase error between the inputs to the detector, and is transferred to the digital loop filter just before the counter is reset.

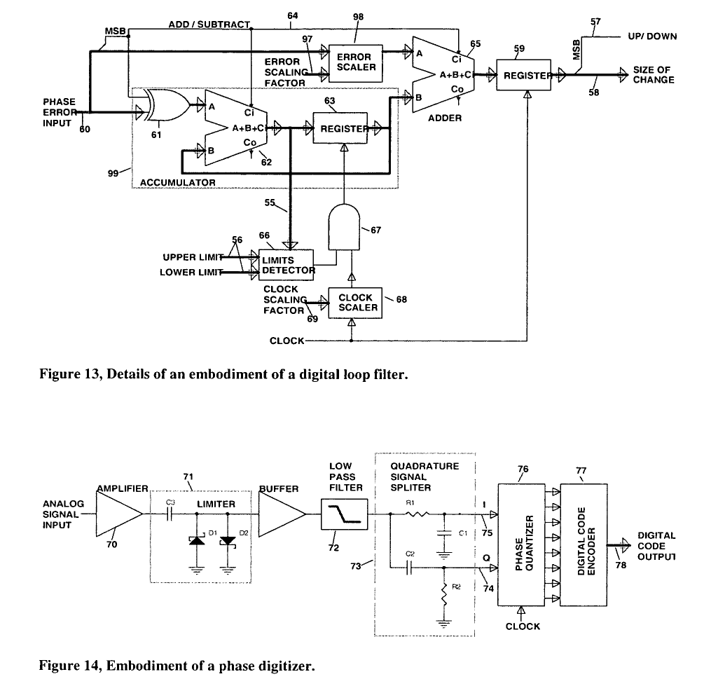

The embodiment of the digital filter is presented in FIG. 13. In the filter an accumulator (99) is sued to accumulate the phase error input (60), on every transition of its clock. The clock rate to the accumulator is scaled by a scaling factor (69) using the clock scaler (68), and then gated by the gate (67). To prevent the accumulator from rolling over when the accumulation reaches 2ⁿ, Or when it goes down to zero, a limit detector (66) is employed. The limit detector (66) monitors the data in the accumulator, to verify that it is between an upper limit and a lower limit (56). If the data goes above the upper limit, or goes below the lower limit, the limit detector causes the gate (67) to block the clock to the accumulator, and prevent it from rolling over. The output of the accumulator is transferred to an adder (65) where it is added to the output of the error scaler (98). The scaler receives the phase error input (60), and scales it by a the error scaling factor (97). The phase error input (60) may be a positive or a negative number, and the accumulator (62) and the adder (65) have to add the error (60) or subtract it, depending of the most significant bit (64) of the error signal (60). The output (58) of the register (59) is the size of change required from the NCO, which follows the filter. The required change may be positive or negative, and the most significant bit (57) of the output data (58) indicates the polarity of the required change.

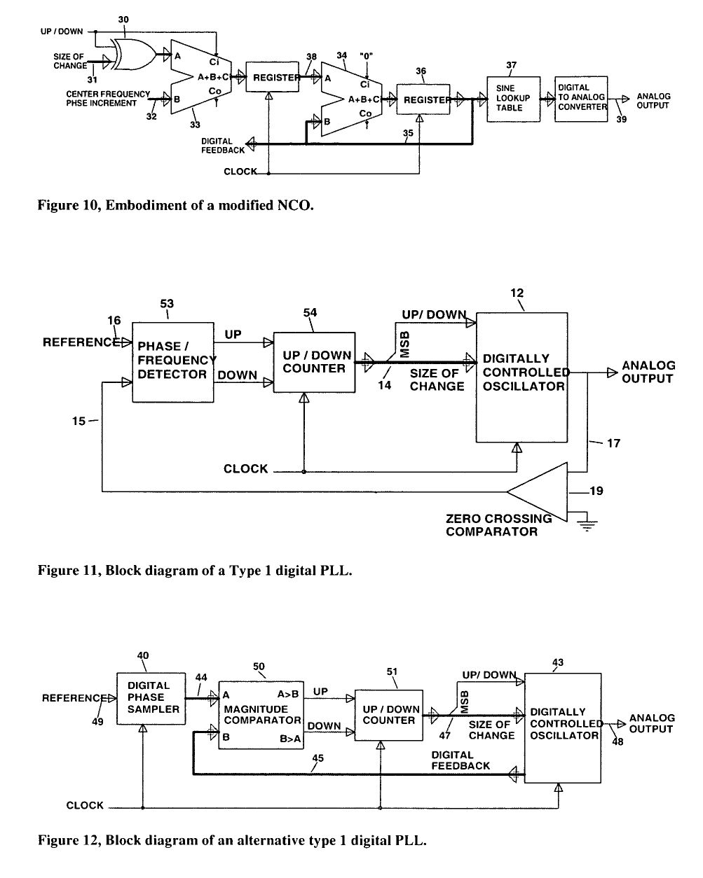

FIG. 10, shows an embodiment of a modified NCO. The basic NCO is comprised of an accumulator followed by a phase to amplitude converter. In the embodiment shown in FIG. 10, the accumulator is comprised of the adder (34) and the register (36). The phase to amplitude converter is comprised of the sine lookup table (37) followed by a digital to analog converter.

Typically in NCOs, the input “A” (38) to the adder (34) determines the output frequency of the NCO. In the embodiment of the NCO, presented in FIG. 10, the input (38), is preceded by an adder (33). On the adder (33), the input “B” receives the phase increment per clock period (32) for the center frequency of the PLL, while on the input “A”, the requested change in frequency (31), as determined by the phase detector and the loop filter, is added, or subtracted, to control the NCO in order to lock the loop.

In a different embodiment of a digital PLL shown in FIG. 9, a phase digitizer (40) and a subtractor (41) replace the phase detector (10) shown in FIG. 7. Also, the feedback (45) is the digital presentation of the instantaneous phase of the NCO, instead of the feedback (15) derived from the analog output, as is the case shown in FIG. 7.

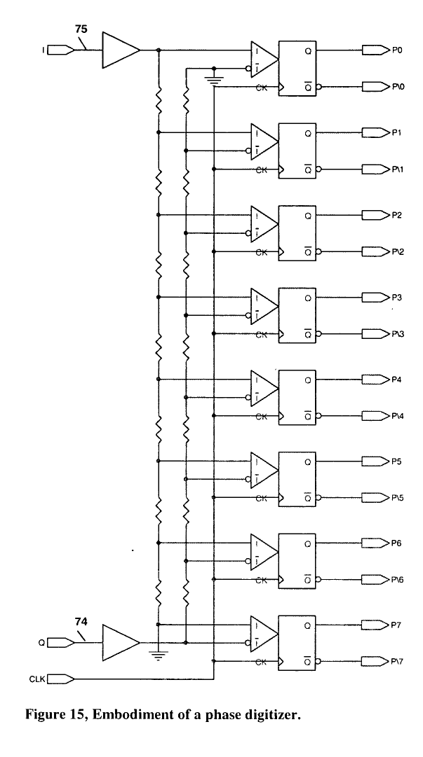

An embodiment of the phase digitizer is shown in FIG. 14, and an embodiment of its quantizer section is shown in FIG. 15. In the digitizer, the input signal is amplified by the amplifier (70), limited by the hard limiter (71), filtered by the lowpass filter (72), to produce a harmonic free sinewave, and then split into by the quadrature signal splitter (73) into two sinewaves, I (75), and Q (75), which are phased 900 from each other. In the phase quantizer (76) the two quadrature inputs (74, and 75) are used to generate n phase shifted sinewaves, wherein the phase difference between any two adjacent sinewaves is 360/n. The quantizer (76) applies these sinewaves to n comparators each combined with a flip-flop. On every clock transition the flip-flops output a pattern unique to the to the phase of the sinewaves (74, 75) at the moment of the clock transition. An encoder (77) follows the quantizer and converts the pattern generated by the quantizer (76) into a Binary code (78).

Referring to FIG. 9, the phase digitizer (40) is followed by a subtractor (41). The subtractor calculates the phase difference between the phase (44) of the reference input signal (49), and the phase (45) of the NCO. The digital filter (42) the follows the subtractor (41), and the NCO (43) that follows the digital filter are similar to the digital filter (11) and the NCO (12) presented in FIG. 7.

1. A digital phase locked loop comprising of:
A modified phase detector;
A digital loop filter;
A numerically controlled oscillator.

2. A modified phase detector as in claim 1, wherein the phase detector produces a numerical output directly proportional to the phase difference between the inputs to the detector.

3. A digital loop filter as in claim 1, comprising of
A digital integrator having a scalable clock rate;
An adder wherein one input not connected to the digital integrator is scalable.

4. A numerically controlled oscillator as in claim 1, wherein two digital inputs are available, one to control the center frequency of the oscillator, and the other to change the frequency in accordance with instructions from the loop filter.

5. A digital phase locked loop comprising of:
A phase digitizer;
A digital subtractor;
A digital loop filter;
A modified numerically controlled oscillator.

6. A phase digitizer as in claim 5, wherein the output of the digitizer in response to an instructing clock pulse, is the instantaneous phase of its input signal at the moment of the instructing clock pulse.

7. A subtractor as in claim 5, wherein the subtractor calculates the difference between the instantaneous phase of the input signal reported by the phase digitizer, and the instantaneous phase of the accumulator in the numerically controlled oscillator at the time of the instructing clock pulse.

8. A digital loop filter as in claim 5, comprising of
A digital integrator having a scalable clock rate;
An adder wherein one input not connected to the digital integrator is scalable.

9. A numerically controlled oscillator as in claim 5, wherein two digital inputs are available, one to control the center frequency of the oscillator, and the other to change the frequency in accordance with instructions from the loop filter.

10. A numerically controlled oscillator as in claim 5, further modified to output the instantaneous phase accumulated by the accumulator.

11. A digital phase locked loop comprising of:
A phase detector;
A digital counter;
A numerically controlled oscillator.

12. A phase detector as in claim 11, wherein the phase detector produces digital commands indicating the polarity of a phase error.

13. A digital counter as in claim 11, capable of counting up or counting down.

14. A numerically controlled oscillator as in claim 1, wherein two digital inputs are available, one to control the center frequency of the oscillator, and the other to change the frequency in accordance with instructions from the loop filter.

15. A digital phase locked loop comprising of:
A phase digitizer;
A digital magnitude comparator;
A digital counter;
A numerically controlled oscillator.

16. A phase digitizer as in claim 15, wherein the output of the digitizer in response to an instructing clock pulse, is the instantaneous phase of its input signal at the moment of the instructing clock pulse.

17. A digital magnitude comparator as in claim 15, wherein the comparator compares the magnitude of the instantaneous phase of the reference input signal, reported by the phase digitizer and the instantaneous phase of the accumulator of the numerically controlled oscillator, and wherein the comparator outputs indicate the polarity of the difference between the phases.
A digital counter as in claim 15, capable of counting up or counting down.

18. A numerically controlled oscillator as in claim 1, wherein two digital inputs are available, one to control the center frequency of the oscillator, and the other to change the frequency in accordance with instructions from the loop filter.

19. A numerically controlled oscillator as in claim 15, further modified to output the instantaneous phase accumulated by the accumulator.
